(19) United States
(12) Patent Application Publication
(10) Pub. No.: US 2026/0020381 A1
(43) Pub. Date: Jan. 15, 2026

(54) MICROLED DISPLAY WITH UNIFORM FEATURE THICKNESS AND METHOD FOR MANUFACTURING THE SAME

(71) Applicant: Google LLC, Mountain View, CA (US)

(72) Inventors: Aurelien Jean Francois David, San Francisco, CA (US); Charles Alexander Forman, Fremont, CA (US); David Paul Bour, Cupertino, CA (US); Melvin Barker McLaurin, Oakland, CA (US); Melissa Jane Archer, San Jose, CA (US); Emel Tasyurek, Santa Clara, CA (US); Rohit Khanna, Odessa, FL (US)

(21) Appl. No.: 19/115,391

(22) PCT Filed: Dec. 30, 2023
(86) PCT No.: PCT/US2023/086565

§ 371 Date: Mar. 26, 2025

(51) Int. Cl. H10H 20/819; H10H 29/37

(52) U.S. Cl. CPC H10H 20/819; H10H 29/37

(57) ABSTRACT

In a general aspect, a microLED display (600) includes a semiconductor member (605a) having a thickness, where the semiconductor member has a LED side (602a) configured to produce light (670) for displaying an image, and an output side (602b) configured to display the image by outputting the produced light, the output side being opposite the LED side. The display also includes a plurality of microLED mesas (627) included on the LED side of the semiconductor member, and a plurality of etched features (655a, 655b, 655c) defined in the semiconductor member. The plurality of etched features are defined on at least one of the LED side or the output side. The plurality of etched features define un-etched portions in the semiconductor member having respective thicknesses that are less than the thickness of the semiconductor member. The respective thicknesses of the un-etched portions are uniform across the display, with a total thickness variation less than 200 nanometers.

### CROSS-REFERENCE TO RELATED APPLICATION

This application claims priority to U.S. Provisional Patent Application No. 63/616,054, filed on Dec. 29, 2023, entitled “MICROLED DISPLAY WITH UNIFORM FEATURE THICKNESS”, the disclosure of which is incorporated by reference herein in its entirety.

### TECHNICAL FIELD

This description relates to emissive display devices, such as emissive displays including micro light emitting diodes (microLEDs or μLEDs).

### BACKGROUND

Emissive displays can be implemented using light emitting diodes (LEDs), such as microLEDs (μLEDs), which can be grouped into pixels of a corresponding display. An LED or μLED of a display can include a semiconductor stack that is produced using a semiconductor process, such as an epitaxial growth process, and can include one or more etched features, where such etched features can enhance optical properties of the display. Variation of an etch process used to produce such etched features, such as across an associated display or an associated wafer, in addition to variation in thickness of layers of the semiconductor stack, can cause variation in dimensions of the etched features that can degrade the benefits of the etched features.

### SUMMARY

In a general aspect, a microLED display includes a semiconductor member having a thickness, where the semiconductor member has a light emitting diode (LED) side configured to produce light for displaying an image, and an output side configured to display the image by outputting the produced light, the output side being opposite the LED side. The microLED display also includes a plurality of microLED mesas included on the LED side of the semiconductor member, and a plurality of etched features defined in the semiconductor member. The plurality of etched features are defined on at least one of the LED side or the output side. The plurality of etched features define un-etched portions in the semiconductor member having respective thicknesses that are less than the thickness of the semiconductor member. The respective thicknesses of the un-etched portions are uniform across the microLED display, with a total thickness variation less than 200 nanometers (nm).

In another general aspect, a microLED display includes a semiconductor member having a light emitting diode (LED) side configured to produce light for displaying an image, and an output side configured to display the image by outputting the produced light. The output side is opposite the LED side. The microLED display also includes a plurality of microLED mesas included on the LED side of the semiconductor member. The plurality of microLED mesas have respective base interfaces with the semiconductor member. The microLED display further includes a plurality of etched features defined in the semiconductor member on the output side. The plurality of etched features have respective bottom surfaces. Respective distances between the respective base interfaces and the respective bottom surfaces are uniform across the microLED display, with a total thickness variation less than 200 nanometers.

In another general aspect, a method for forming a microLED display includes attaching a semiconductor stack to a backplane, where the semiconductor stack includes a substrate, a semiconductor template having a first etch-stop layer and a second etch-stop layer included therein, and LED layers. The attaching electrically couples the backplane to the LED layers. The method further includes removing the substrate, and etching the semiconductor template with a first etch process. The first etch process has a first etch rate for a first portion of the semiconductor template and a second etch rate for the first etch-stop layer. The second etch rate is slower than the first etch rate. Etching the semiconductor template produces lateral regions of the semiconductor template with a first uniform thickness. The method also includes etching the lateral regions of the semiconductor template with a second etch process having a third etch rate for a second portion of the semiconductor template and a fourth etch rate for the second etch-stop layer. The fourth etch rate is slower than the third etch rate. Etching the lateral regions of the semiconductor template defines un-etched portions of the lateral regions having a second uniform thickness that is less than the first uniform thickness.

### BRIEF DESCRIPTION OF THE DRAWINGS

FIGS. 1A to 1F are diagrams illustrating an example process for forming an LED display.

FIGS. 2A to 2F are diagrams illustrating another example process for forming an LED display.

FIGS. 3A to 3F are diagrams illustrating yet another example process for forming an LED display.

FIGS. 4A and 4B arc diagrams illustrating example microLED displays that can be produced using the processes of FIGS. 1A to 1F, FIGS. 2A to 2F, or FIGS. 3A to 3F.

FIG. 5 is a diagram illustrating another example microLED display.

FIG. 6 is a diagram illustrating a portion of an example emissive display.

FIG. 7 is a diagram illustrating an epitaxially formed stacked that can be used to produce microLEDs of a microLED display.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in the same view, or in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated in a given view.

### DETAILED DESCRIPTION

As noted above, variations in etch rate, e.g., across a display or a wafer, for etch processes used for forming etched features of a display, such as a light emitting diode (LED) display, or a microLED (μLED) display, can result in associated variations in dimensions of such etched features. For instance, a dry etch tool, such as a reactive-ion etcher (RIE) or an inductively-coupled plasma (ICP) etcher, can have variations in etch rate across a display, or a wafer used when producing a display, which are on the order of +/−5%. Accordingly, by way of example, for an epitaxial stack with a nominal thickness of 5 micrometers (μm), and etching a feature to a depth of 4.5 μm with a target remaining thickness of 500 nanometers (nm) of un-etched material, the actual etch depth of corresponding etched features across an associated display or wafer, can be in an approximate range from 4.3 μm to 4.7 μm. In other words, corresponding un-etched portions of the etched features across a region of interest can have a total thickness variation (TTV) of 400 nm associated with the etch process. Furthermore, variation in thickness of epitaxial layers used for producing μLEDs across an associated display or wafer can also be on the order of +/−5%. This additional variation can further increase the TTV, for example, resulting in a TTV of 800 nm. In some implementations, it is desirable to define such etched features with uniform thickness, or well-controlled TTV, such as a TTV less than 300 nm, less than 200 nm, or less than 100 nm.

This disclosure is directed to displays having such uniform thicknesses for regions associated with such etched features, and associated methods for producing such displays. For purposes of this disclosure, and by way of example, the approaches and techniques described herein are generally discussed with respect to displays that include μLEDs, which can be referred to as a μLED display, or a display. In some implementations, the approaches and techniques described herein can be used for displays including other types of light emitters.

In some implementations, a display can include a semiconductor template (template), such as those described herein, and etched features formed in the template. The template may have a uniform thickness, which can be achieved using disclosed approaches. Furthermore, in example implementation described herein, un-etched portions of a template associated with the etched features, e.g., that are defined by the etched features, can have a uniform thickness, such as with a TTV as described herein. Such un-etched portions can be a remaining thickness of a corresponding template after formation of an associated etched feature.

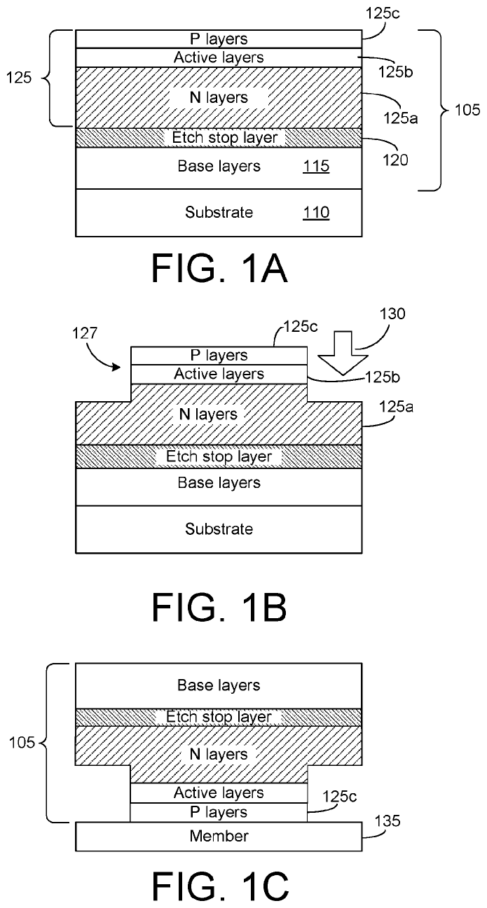

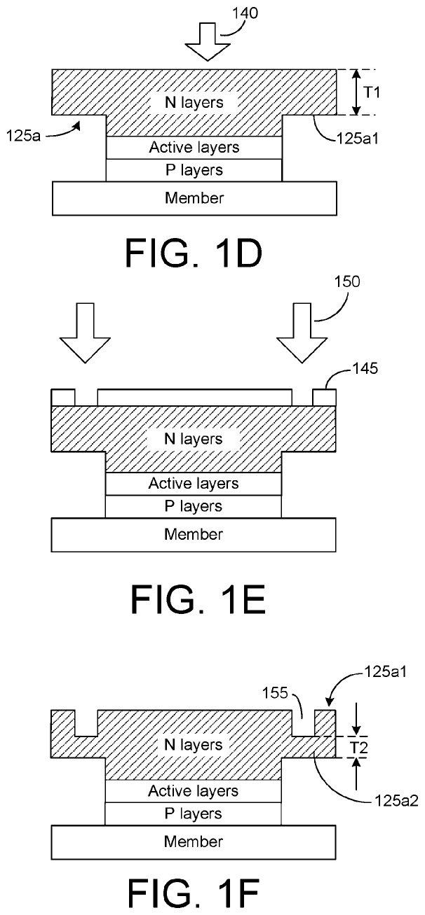

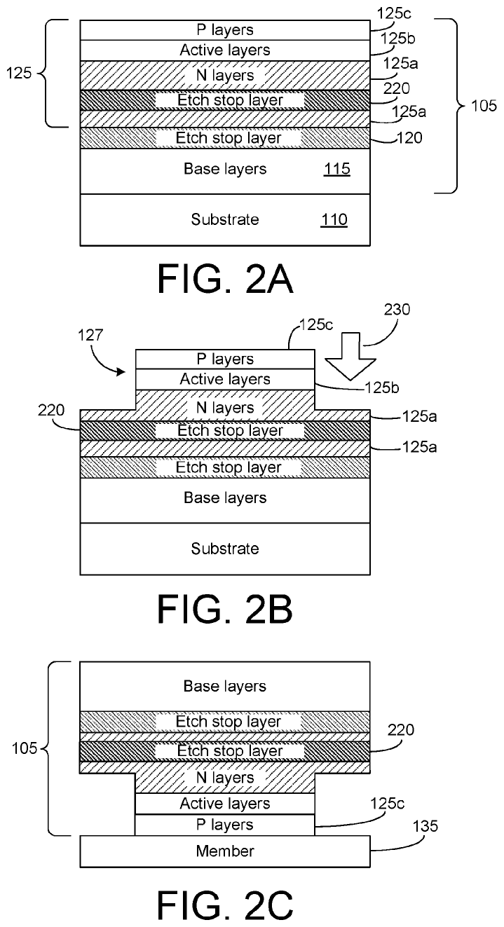

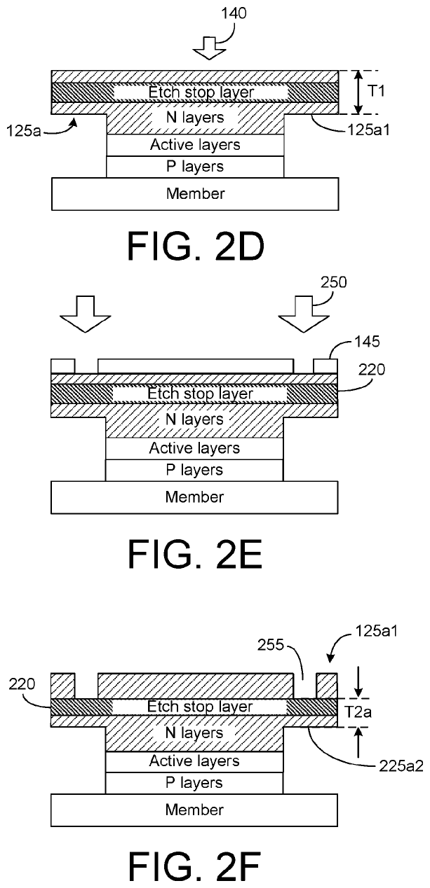

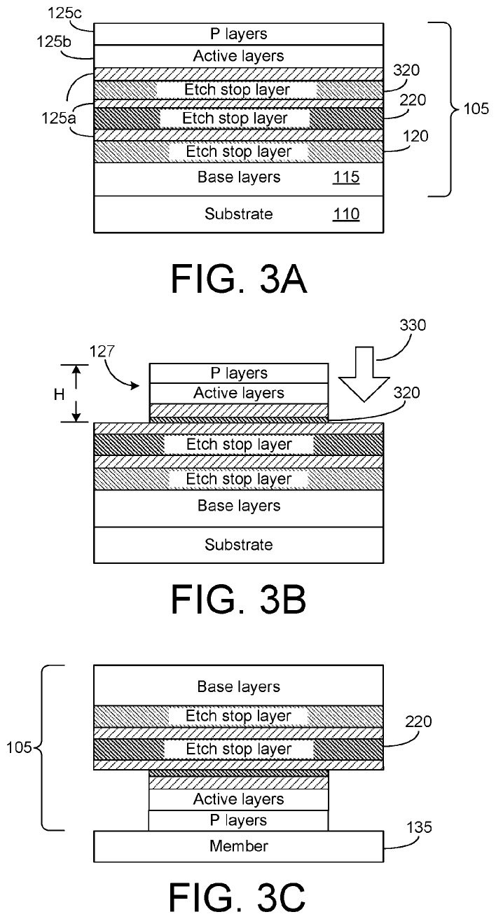

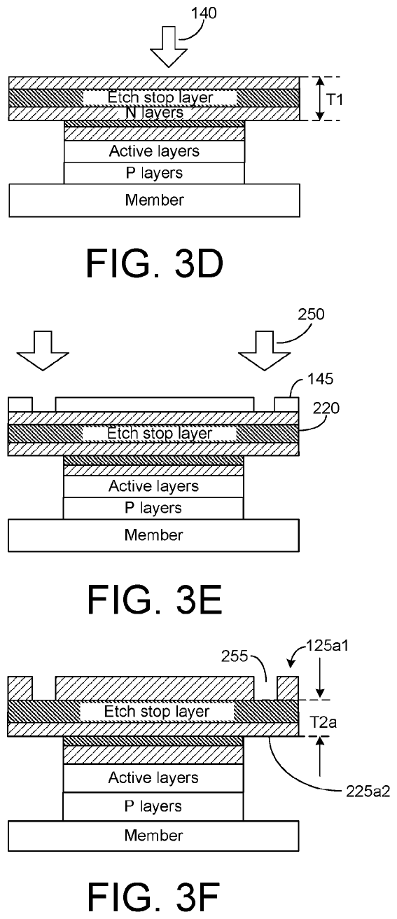

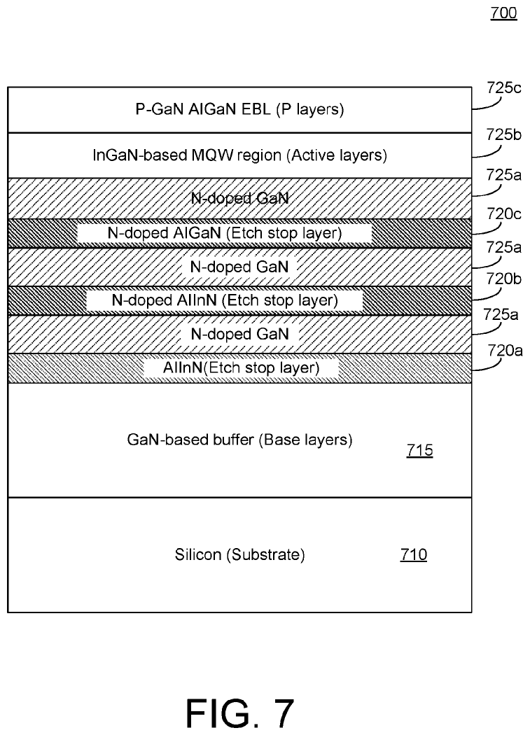

FIGS. 1A to 1F are diagrams illustrating an example fabrication process for forming a μLED display having etched features with well-controlled thicknesses of associated semiconductor materials. In FIGS. 1A to 1F, a single μLED is illustrated by way example. However, the process of FIGS. 1A and 1F, and other processes described herein, can be used to produce an array of μLEDs, such as an array including a plurality of red μLEDs, a plurality of green μLEDs, and plurality of blue μLEDs. The μLEDs of such an array can be arranged so as to implement a plurality of pixels of a corresponding display. Furthermore, in the fabrication process of FIGS. 1A to 1F, as well as the respective fabrication processes of FIGS. 2A to 2F and FIGS. 3A to 3F, general reference is made to materials that can be used for fabrication. Further details regarding example materials of a display are discussed below, such as with reference to, at least, FIG. 7.

As shown in FIG. 1A, a semiconductor stack 105 can be formed on a substrate 110. In some implementations, the semiconductor stack 105 can be grown using one or more epitaxial operations. The semiconductor stack 105, in this example, includes base layers 115, an etch-stop layer 120 (which can be an etch-selective layer in some implementations), and LED layers 125. The LED layers 125 include n-type layers 125a, active layers 125b, such as active quantum well (QW) layers, and p-type layers 125c. In some implementations, the active layers 125b can include one or more indium gallium nitride (InGaN) QW layers.

As shown in FIG. 1B, after forming the semiconductor stack 105, an etch 130 can be performed to form a μLED mesa 127. Forming the μLED mesa 127 with the etch 130 can include etching through the p-type layers 125c, the active layers 125b, and at least part of the n-type layers 125a. While not specifically shown, the etch 130 of FIG. 1B can be performed using a hard mask, where the hard mask prevents the etch 130 from etching respective portions of the p-type layers 125c, the active layers 125b, and the n-type layers 125a that are included in the μLED mesa 127.

As shown in FIG. 1C, after forming the μLED mesa 127 (and other LED mesas of an arrays of μLEDs of a corresponding display), the semiconductor stack 105 is coupled with a mounting member 135 via the p-type layers 125c, and the substrate 110 is removed from the semiconductor stack 105. In some implementations, the substrate 110 can be removed using a lift-off process, though other approaches, such as etching and/or grinding are possible. In some implementations, the mounting member 135 can be a complimentary metal-oxide semiconductor (CMOS) backplane that is used to drive μLEDs of a corresponding display, such as the μLED mesa 127.

As shown in FIG. 1D, after removing the substrate 110, the base layers 115 are etched, e.g., removed, using an etch process 140, where the etch-stop layer 120, depending on the particular implementation, slows or stops the etch process 140. For instance, in this example, the etch-stop layer 120 is fully removed. In some implementations, the etch process 140 can be stopped at an upper surface of the etch-stop layer 120 (in the view of FIG. 1C), or within the etch-stop layer 120, such that all, nearly all, or some portion of the etch-stop layer 120 remains after the etch process 140. As shown in FIG. 1D, the etch process 140 results in lateral portions 125a1 of the n-type layers 125a with a well-controlled thickness T1 being defined.

After performing the etch process 140, as illustrated in FIG. 1E, a hard mask 145 is formed on the n-type layers 125a, and an etch process 150 is performed through openings in the hard mask 145. As shown in FIG. 1F, the etch process 150 results in formation of etched features 155 in the n-type layers 125a with a well-controlled shape and/or well-controller depth. For instance, as shown in FIG. 1F, the etched features 155 formed by the etch process 150 define un-etched portions 125a2 of the lateral portions 125a1 with a well-controlled thickness T2.

In example implementations, using the approaches described herein, the well-controlled thickness T2 can have a TTV that is less than 200 nm, less than 100 nm, less than 50 nm, or less than 10 nm across a region of interest, e.g., a lateral region of interest of a display or wafer of a display. In some implementations, the well-controlled thickness T2 can be less than 500 nm, less than 300 nm, or less than 100 nm. The well-controlled thickness T2 can be greater than 50 nm, greater than 100 nm, or greater than 200 nm. In some implementations, the lateral region of interest can have an area of at least 0.01 cm², at least 0.1 cm², at least 1 cm², at least 10 cm², or at least 100 cm². The lateral region of interest may encompass at least 1%, at least 10%, or at least 50% of an area of a semiconductor wafer being processed to produce a corresponding display

In the process of the FIGS. 1A to 1F, as well as other processes described herein, the substrate 110 may include silicon, sapphire, bulk gallium nitride (GaN), and/or a GaN-containing material. The base layers 115 may include a stack of semiconductor material. For instance, the base layers 115 can be a GaN-based stack, such as a multilayer stack of GaN and aluminum gallium nitride (AlGaN). In some implementations, the base layers 115 can have a thickness that is greater than 1 μm, greater than 2 μm, greater than 3 μm, greater than 4 μm, or greater than 5 μm. While this disclosure is generally directed to displays produced using III-Nitride materials, in some implementations, other semiconductor materials can be used to produce a display using the approaches described herein.

As noted above, in some implementations, the etch-stop layer 120, or a portion of the etch-stop layer 120, can remain after performing the etch process 140, such as if the etch process 140 is selective enough that it does etch, or does not fully etch the etch-stop layer 120. In such implementations, the etch-stop layer 120, or a portion of the etch-stop layer 120 can be retained through processing operation subsequent to the etch process 140. In other example implementations, an additional processing operation can be performed to remove any portion of the etch-stop layer 120 remaining after the etch process 140, such as another etch process (e.g., a dry etch and/or a wet etch), which may selectively remove any residual portion of the etch-stop layer 120.

In some implementations, the fabrication process of FIGS. 1A to 1F, as well as the respective fabrication processes of FIGS. 2A to 2F and FIGS. 3A to 3F, can be implemented using etch-stop layers and/or etch-selective layers, such as for the etch-stop layer 120 or other such layers. For instance, as used herein, an etch-stop layer is a layer that is negligibly etched during an etch step, such that the etch-stop layer is substantially un-etched at the end of the etch step (e.g. at least 80% of its thickness remains). An etch-selective layer is a layer with etch rate that is small compared to an etch rate of a target material being etched or removed, such as the base layers 115 with the etch process 140. For instance, a target material may have an etch rate R1, and the etch-selective material may have an etch rate R2, with a ratio of R1 to R2 being at least 2, at least 3, at least 5, at least 10, at least 15, at least 20, or at least 50. In some implementations, the target material being etched is GaN. Although reference is generally made to etch-stop materials in this specification, etch-selective materials may also be used.

The mounting member 135 can include circuitry to drive μLEDs of a display. For instance, as noted above, the mounting member 135 can be a CMOS backplane. In other implementations, the mounting member 135 can be a backplane having other configurations, such as glass with flat circuitry, e.g., a low-temperature polycrystalline silicon (LTPS) circuit.

Such as shown in FIG. 1C, as well as in other fabrications processes described herein, an electrical contact is formed between the mounting member 135 and the semiconductor stack 105. In the example of FIG. 1C, a metal p-contact (e.g. a metal stack) can be formed on the p-type layers 125c, such as before the etch 130, wherein the etch 130 also removes portions of the metal p-contact during formation of the LED mesa 127. In some implementations, the mounting member 135 can have a second metal contact, and an electrical contact can be formed between the p-contact on the p-type layers 125c and the and second metal contact on the mounting member 135.

In some implementations, a semiconductor stack 105, such as the semiconductor stack 105, can be formed on an LED wafer. A mounting member, such as the mounting member 135, can be a CMOS backplane implemented on a silicon wafer. In such implementations, the LED wafer can be attached to the CMOS wafer by wafer-to-wafer bonding. In some implementations, the LED wafer can be singulated into separate μLED die, and each μLED die can be respectively attached to a CMOS backplane wafer using die-to-wafer bonding. In some implementations, a bonding process for coupling μLEDs with a backplane can include hybrid bonding processes.

In some implementations, a thickness of a mounting member, such as the mounting member 135, can be at least 50 μm, at least 100 μm, or at least 500 μm. In some implementations, a mounting member can have a thickness that is less than 1 millimeter (mm), less than 0.5 mm, or less than 0.1 mm. In some implementations, a mounting member can be thinned during a fabrication process, such as using an etch process, a chemical process, and/or a mechanical process.

The etched features 155 shown in FIG. 1F may be used to affect optical properties of a resulting μLED, e.g., implemented by the μLED mesa 127. In some implementations, the etched features 155 can be configured to increase light extraction, e.g. by redirecting or scattering light outside the LED. In some implementations, the etched features 155 are configured to reduce optical cross-talk between μLEDs or pixels, such as cross-talk between adjacent μLEDs and/or adjacent pixels of a display.

In some implementations, a display, such as a μLED display, can have etched features similar to the etched features 155 shown in FIG. 1F. Such etched features can be trenches or, in some implementations, the etched feature can be etched regions of various shapes, such as holes, slanted holes, inverted pyramics, and so forth. Sidewall slopes of such etched regions can be configured for a desired optical property. For instance, in some implementations, a sidewall can form an angle from vertical that is between 20 degrees and 70 degrees, which can promote light extraction, for example, from an LED side of a display to an output side of the display that is opposite the LED side.

FIGS. 2A to 2F are diagrams illustrating another example process for forming an LED display. The process of FIGS. 2A to 2F is a variation of the process of FIGS. 1A to 1F. Accordingly, similar or like elements of FIGS. 2A to 2F are referenced with the same 100-series reference numbers of FIGS. 1A to 1F. In the process of FIGS. 2A to 2F, the operations illustrated by FIGS. 2A to 2D can follow a same fabrication processing flow as FIGS. 1A to 1D. Therefore, for purposes of brevity, the details discussed above with respect to FIGS. 1A to 1D are not repeated with respect to FIGS. 2A to 2D.

As compared with the example of FIGS. 1A to 1F, the semiconductor stack 105 of FIGS. 2A to 2F, such as shown in FIG. 2A, includes an etch stop layer 220 (e.g., in addition to the etch-stop layer 120). In this example, the etch stop layer 220 can be configured to stop or slow an etch process 250 to facilitate formation of etched features 255, such that unetched portions 225a2 of the lateral regions 125a1 have a well-controlled thickness T2a. This variation can allow for improved control of a TTV of the unetched regions 225a2 defined by the etched features 255 over a lateral region of interest of a corresponding display. That is, the etch stop layer 220 can facilitate slowing or stopping the etch process 230 in a vicinity of, or proximate the etch stop layer 220 to control a TTV of the unetched portions 225a2 that are defined by the etched features 255.

FIGS. 3A to 3F are diagrams illustrating yet another example process for forming an LED display. The process of FIGS. 3A to 3F is a variation of the process of FIGS. 2A to 2F (which is a variation on the process of FIGS. 1A to 1F). Accordingly, similar or like elements of FIGS. 3A to 3F are referenced with the same 100-series reference numbers of FIGS. 1A to 1F, or the same 200-series reference numbers as FIGS. 2A to 2F. In the process of FIGS. 3A to 3F, the operations illustrated by FIGS. 3C to 3F can follow a same fabrication processing flow as FIGS. 2C to 2F (as well as FIGS. 1C and 1D). Therefore, for purposes of brevity, the details of the operations of FIGS. 3C to 3F are not described again here.

As compared with the example of FIGS. 2A to 2F, the semiconductor stack 105 of FIGS. 3A to 3F, such as shown in FIG. 3A, includes an etch stop layer 320 (e.g., in addition to the etch-stop layer 120 and the etch stop layer 220). In this example, the etch stop layer 320 is configured to stop or slow an etch process 330 to facilitate formation of the LED mesa 127 with a well-controlled height H. That is, the etch stop layer 320 can facilitate slowing or stopping the etch process 330 in a vicinity of, or proximate the etch stop layer 320.

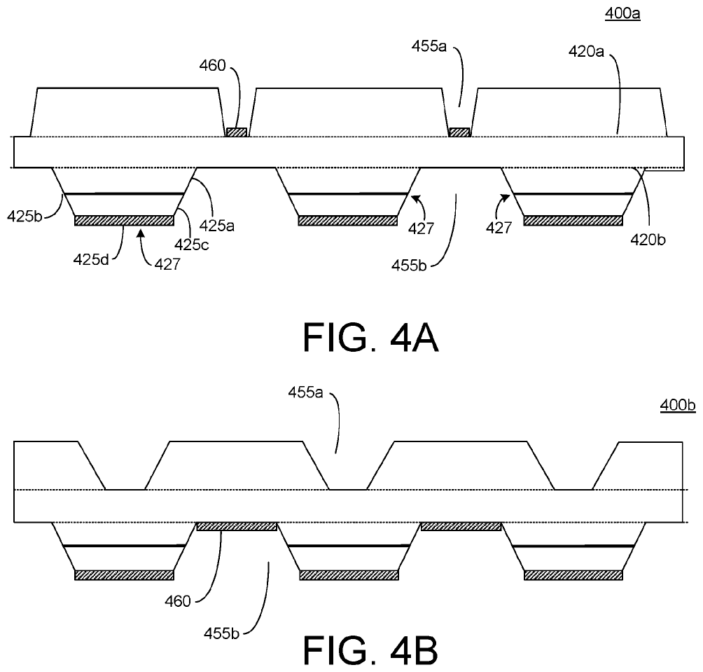

FIGS. 4A and 4B are diagrams illustrating cross-sectional views of portions of example microLED displays that can be produced using the fabrication processes of FIGS. 1A to 1F, FIGS. 2A to 2F, and/or FIGS. 3A to 3F. For instance, FIG. 4A illustrates a cross-sectional view of a display 400a with LED mesas 427. As shown in FIG. 4A, a LED mesa 427 includes an n-type region 425a, an active region 425b, a p-type region 425c, and a p-contact 425d. In example, implementations, the active region 425b can include a plurality of InGaN quantum wells. The p-contact 425d can include a metal layer, such as a silver-based contact that is formed on the p-type region 425c.

As shown in FIG. 4A, n-side trenches 455a and p-side trenches 455b are defined in a corresponding semiconductor stack. In this example, the p-side trenches 455b can be referred to as being formed in an LED side of the display 400a, while the n-side trenches 455a can be referred to as an output side of the display 400a. In such an implementation, light for rendering an image can be produced by the LED mesas 427 on the LED side of the display 400a, and that light can be directed to the output side of the display 400a for displaying the corresponding image.

As further shown in FIG. 4A, n-contacts 460 are respectively disposed in the n-side trenches 455a. In this example, the p-side trenches 455b terminate at a p-side etch-stop interface 420b, which can be facilitated using an etch-stop layer or an etch-selective layer, such as described herein. Likewise, the n-side trenches 455a terminate at an n-side etch-stop interface 420a, which can also be facilitated using an etch-stop layer or an etch-selective layer, e.g., using the approaches described herein. A thickness between the n-side etch-stop interface 420a and the p-side etch-stop interface 420b can, using the approaches described herein, be well-controlled. For instance, the thickness between the n-side etch-stop interface 420a and the p-side etch-stop interface 420b can have a TTV of less than 500 nm, less than 200 nm, less than 100 nm, or less than 50 nm across a lateral region of interest, such as across the display 400a.

FIG. 4B illustrates a cross-sectional view of a display 400b, which is an alternate configuration to that of the example of FIG. 4A. In the display 400b, n-contacts 460 are formed on an LED side (or on a p-side) of the display 400b, e.g., in a flip-chip like configuration in the p-side trenches 455b. In this example, a portion of the semiconductor template can be n-doped to form the n-contacts 460. In some implementations, conductive vias can be etched in the template from the LED side to expose a desired portion of the n-doped material and make the n-contacts 460.

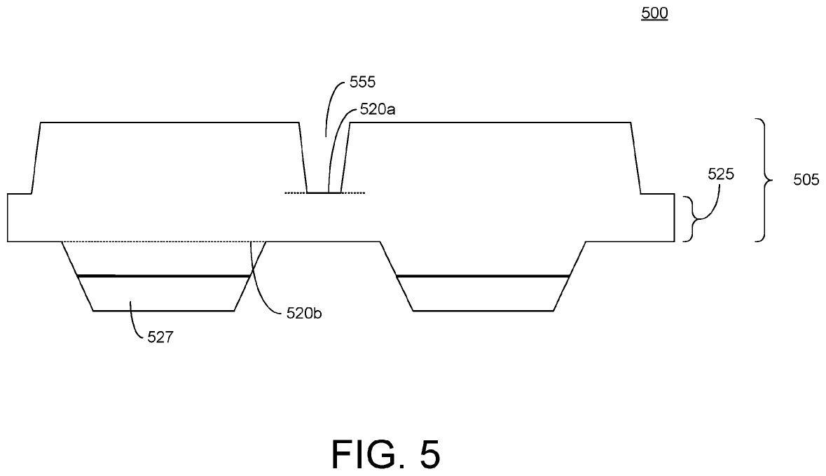

FIG. 5 is a diagram illustrating a cross-sectional view of a portion of another example μLED display 500. Specifically, example geometries of a μLED display are illustrated by the μLED display 500. As shown in FIG. 5, the μLED display 500 includes a semiconductor member 505, which can be a GaN-based template. The semiconductor member 505 has LED mesas 527 formed on one of its sides, which can be referred to as an LED side, such as was discussed above. In this example, the LED mesas 527 have base interfaces 520b, which are interfaces between the LED mesas 527 and the semiconductor member 505. In operation, the μLED display 500 emits display light of one more images from a side opposite the LED side, which can be referred to as a display side, such as also discussed above.

As shown in FIG. 5, the semiconductor member 505 has etched features 555 with bottom interfaces 520a, which can also be referred to as bottom surfaces. The bottom interfaces 520a correspond to respective deepest portions of the etched features 555. While the etched features 555 in FIG. 5 are illustrated as having planar bottoms. In some implementations, etched features having other shapes, such as those noted above, can be defined in the semiconductor member 505.

As further shown in FIG. 5, an un-etched portion 525 of the semiconductor member 505 is disposed between the base interfaces 520b and the bottom interfaces 520a. Using the approaches described herein, the un-etched portion 525 can have a well-controlled, uniform thickness. For instance, in some implementations, the uniform thickness of the un-etched portion 525 can have a low TTV across the μLED display 500, or a low TTV across a wafer on which the μLED display 500 is fabricated. In some implementations, the TTV of the un-etched portion 525 can be less than 300 nm, less than 200, of less than 100 nm. In some implementations, etched features can have an apex, rather than a flat, or planar bottom surface, such the etched features 555 of FIG. 5. In such implementations, a plane defined by the respective apexes can define a bottom interface, such as the bottom interfaces 520a.

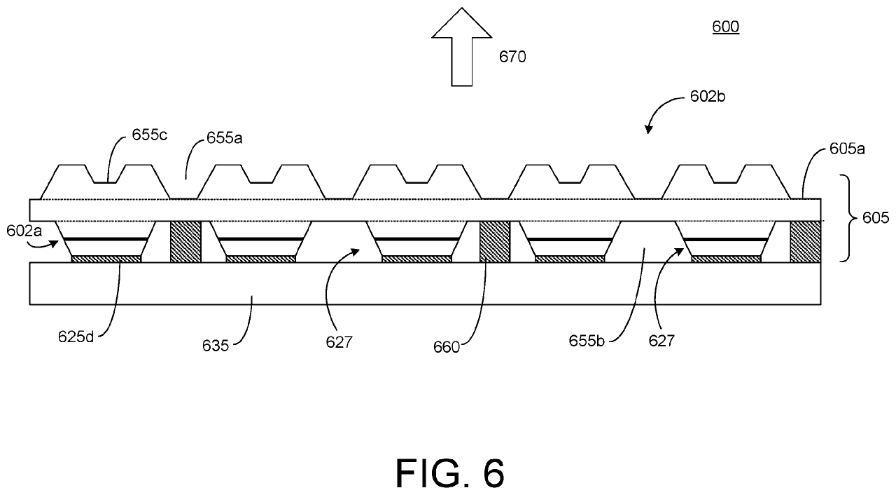

FIG. 6 is a diagram illustrating a cross-sectional view of a portion of another example emissive display 600. As shown in FIG. 6, a LED plane 605 is attached to a backplane 635. The LED plane 605 can be a μLED display that is fabricated using the approaches described herein. In some implementations, the backplane 635 can be a silicon-based CMOS display driver. In this example, the LED plane 605 includes a semiconductor member 605a and a plurality of LED mesas 627, where the plurality of LED mesas 627 can be arranged to form pixels, or sub-pixels of the emissive display 600.

The emissive display 600 also includes etched features 655a, 655b and 655c. In this example, the etched features 655b are formed in the LED plane 605 on an LED side 602a. That is, the etched features 655b are formed in a side of the LED plane 605 that emits light for display of one more images. Further in this example, the etched features 655a and the etched features 655c are formed in the LED plane 605 on an output side 602b, which is opposite the LED side 602a. In this example, the LED plane 605 outputs the light emitted by the plurality of LED mesas 627 disposed on the LED side 602a of the LED plane 605 via (from, etc.) the output side 602b. As shown in FIG. 6, the light can be output by the emissive display 600 in a direction 670.

In example implementations, respective depths of the etched features 655a, 655b and 655c are, using the approaches described herein, well-controlled, facilitating low TTV in unetched portions of the semiconductor member of the LED plane 605 defined by the etched features. As described herein, the etched features 655a, 655b and 655c can serve a number of functions. Accordingly, well-controlled depths for the etched features 655a, 655b and 655c can be desirable for at least the following reasons.

In some implementations, the etched features 655b can enable formation of flip-chip type contacts 625d on the LED plane 605. Having a well-controlled depth for the etched features 655b is desirable to ensure accuracy of respective positions of the flip-chip type contacts 625d on the LED plane 605. Further, well controlled depths for the etched features 655b can facilitate proper contact with n-contacts 660.

In some implementations, the etched features 655a, 655b and/or 655c can facilitate light reflection and/or light scattering and, as a result, increase light extraction from the LED plane 605, which can, for example, increase display brightness. For instance, well-controlled, uniform etch depths for the etched features can facilitate uniform light extraction and uniform brightness across the emissive display 600.

Furthermore, deep etched features can be beneficial for reducing cross-talk between pixels, where cross-talk can refer to an amount of light generated by one pixel that reaches a neighboring pixel before escaping the emissive display 600. Such cross-talk prevention can improve image display contrast of a corresponding display, such as the emissive display 600. In this example, forming deep etched features 655a and 655b, can result in corresponding un-etched regions being thin, for example, less than 500 nm, less than 400 nm, less than 300 nm, less than 200 nm, or less than 100 nm). Also, depth control using the techniques described herein can prevent punch-through of the etched features, e.g., where no un-etched portion remains.

In some implementations, displays with etched features, such as the emissive display 600, can operate with light extraction of at least 10%, at least 20%, at least 30%, or at least 40%. In some implementations, displays with etched features, such as the emissive display 600, can operate with light extraction that is uniform, e.g., less than +/−10%, less than +/−5%, or less than +/−1% across the display. In some implementations, displays with etched features, such as the emissive display 600, can operate with cross-talk less than 5%, less than 2%, less than 1%, or less than 0.1%. While the etched features of the example implementations described here are illustrated as voids, or open space, in some implementations, such etched features can be filled. For instance, in some implementations, etched features of a μLED display can be filled with a dielectric layer, and/or a reflective material (e.g., a metallic layer)

FIG. 7 is a diagram illustrating a semiconductor stack 700 that can be used to produce microLEDs of a microLED display, such as those described herein. In some implementations, the semiconductor stack 700 can be formed using one or more epitaxial process operations. In an example display, the semiconductor stack 700 can be an implementation of the semiconductor stack 105 of FIG. 3A, with specific materials being indicated. For instance, in this example, the semiconductor stack 700 is GaN-based and is grown on a silicon substrate 710.

The semiconductor stack 700 includes a GaN-based buffer 715, which can include multiple GaN-based layers. The semiconductor stack 700 further includes, an etch stop layer 720a, an etch stop layer 720b and an etch stop layer 720c, which are alternated with (e.g., respectively separated by) n-doped GaN layers 725a. In this example, the etch stop layer 720a is an AlInN etch-stop layer, the etch stop layer 720b is an AlInN etch-stop layer, and the etch stop layer 720c is an AlGaN etch-stop layer.

In the view of FIG. 7, an active region 725b is disposed on an uppermost of the n-doped GaN layers 725a. In this example the active region 725b includes a plurality of InGaN QWs that are separated by quantum barriers. The active region 725b can be referred to as a multiple QW (MQW) active region. The quantum barriers of the active region 725b can include GaN and/or AlGaN layers. Further in this example, p-doped layers 725c including p-type GaN and an AlGaN electron blocking layer are disposed on the active region 725b. A number of variations from the semiconductor stack 700 in the example of FIG. 7 are possible, such as composition and doping of the etch-stop layers.

In example implementations of the fabrication processes described herein, an etch operation can include a plurality of sub-operations with varying etch conditions. In one example, a first sub-operation can have an etch rate that is material-independent, and a second sub-operation that has a material-selective etch rate. In some implementations, a selectivity ratio between an etch-stop material (e.g. AlGaN) and another material (e.g. GaN) can be at least 2:1, at least 5:1, are least 10:1, or at least 100:1. In some implementations, an etch operation can switch from a first sub-operation to a second sub-operation in a vicinity of an etch-stop layer, for example, when, or shortly before the etch-stop layer is reached, at a point within the etch-stop layer, or shortly after removal of the entirety, or majority of the etch-stop layer.

In some implementations, a marker layer can be used, where the marker layer can contain a chemical species that is detected during the etch, such as by a mass spectrometer, where detection of the chemical species indicates that the marker layer has been reached by the etch operation. For instance, a GaN-based epitaxial stack can contain an InGaN marker layer and an AlGaN etch-stop layer that are located, by depth in an associated semiconductor stack, less than 500 nm, less than 200 nm, or less than 100 nm from each other. In this example, an etch operation can start with a non-selective etch process that is relatively fast. When In (the marker species) is detected, that indicates that the etch operation has reached the marker layer, and etch conditions can be changed to a selective etch process that is relatively slow, and has an etch rate that is even slower etch rate for the etch-stop layer. The etch operation can then proceed for a predetermined time, e.g., to achieve a desired target thickness for a given etch operation. In some implementations, such as those described herein, several etch-stop layers may be combined. For instance, as in the example fabrication process of FIGS. 3A to 3F, different etch-stop layers can be used to stop corresponding etch operations, such as an LED mesa etch, a template thinning etch, and an etched feature (e.g., trench) etch.

In example implementations, thickness control can be achieved as follows. Epitaxial growth can be configured such that a relative thickness variation of a produced semiconductor stack (e.g., TTV across a region of interest) of less than +/−20%, less than +/−10%, less than +/−5%, less than +/−2%, or less than +/−1% is achieved. In some implementations, LED layers can have a total thickness that is less than 2 μm, less than 1.5 μm, less than 1 μm, or less than 500 nm and, therefore, an absolute TTV of less than +/−200 nm, less than 100 nm, less than 50 nm, less than 20 nm, less than 10 nm, or less than 5 nm. Depth variation caused by etch operations, such as a cumulative variation from a first etch operation and a second etch operation, can be less than +/−150 nm, less than +/−100 nm, less than +/−50 nm, less than +/−20 nm, less than +/−10 nm, or less than +/−5 nm. For instance, in some implementations, a second etch operation can have a relative etch variation across a lateral region of interest that is less than +/−10%, or less than +/−5%, and a depth of the second etch operation can be less than 1.5 μm, less than 1 μm, or less than 500 nm, which can facilitate such depth variations. A total variation in a thickness of residual portions (e.g., un-etched portions) of an associated layer can, therefore, be less than +/−350 nm, less than +/−200 nm, less than +/−100 nm, less than +/−50 nm, less than +/−20 nm, or less than +/−10 nm. The lateral region of interest for TTV can encompass an area of a corresponding display with dimensions of, for example, at least 1 mm×1 mm, a disc with a radius of at least 50 mm, the area of a wafer, or the area of a wafer minus an edge exclusion zone of at least 5 mm, or in a range 5 to 20 mm.

In some implementations, a template can be produced or provided, where the template includes one or several layers for facilitating thickness control, such as etch-stop layers, marker layers, etc. For instance, a template can be formed on a substrate, which can be silicon, sapphire, or can include other materials. In some implementations, a template can include AlGaN nucleation/stress-management layers, and one or more GaN buffer layers with one or more etch-stop layers sandwiched in the GaN buffer layers. Epitaxial regrowth can then be performed on the template. During the regrowth, an LED region can be grown. The regrown layers can further include one or more layers to facilitate thickness control.

In some implementations, etch-stop layers can be formed while mitigating the bow of a wafer, whether a template wafer or a wafer with an LED structure. For instance, in such implementations, bow of a wafer may be less than 100 μm, less than 50 μm, less than 20 μm, less than 10 μm, less than 5 μm, less than 2 μm, or less than 1 μm. The wafer may have a diameter of at least 50 mm, at least 75 mm, at least 100 mm, at least 150 mm, or at least 200 mm. Bow control can be facilitated by tuning strain and thickness of layers. In some examples, lattice-matched layers can be used as an etch-stop layer and/or as a marker layer. For III-nitrides, Al(x)In(y)Ga(1−x−y)N compounds can provide lattice matching to a desired lattice constant. In the case of GaN, lattice matching can also be achieved by Al(x)In(1−x)N with x˜83%.

In some implementations, such as the examples described herein, semiconductor materials can include III-V semiconductors, such as III-nitride semiconductors such as GaN, AlGaN, InGaN. Dielectric materials used can include SiOx, SiNx, SiOxNy, AlOx, and/or TiOx.

Etch-stop layers can include III-nitrides, such as AlGaN, AlInN, and/or AlInGaN, which can have an Al percentage composition of greater than 20%, greater than 30%, or greater than 50%. Etch-stop layers can be substantially lattice-matched to associated base layers, for example, AlInN with Al %=83% lattice-matched to a GaN template. Etch-stop layers can include a dielectric material, such as a patterned dielectric layer embedded in associated epitaxial growth, e.g., formed by lateral overgrowth. In one example, an etch-stop layer can include Al_{0.2}GaN with a thickness of about 50 nm.

Etch methods/material removal methods can include dry etch, such as RIE, ICP etch, wet etch (including chemical etch), photo-chemical or photo-electro-chemical etch, and/or sputtering. Dry etches can have various chemistries including fluorine-based (e.g., CF4), chlorine-based (e.g., Cl2), argon-based, oxygen-based, and combinations of these species. Photoelectrochemical (PEC) etching can be used to selectively etch low-bandgap materials, e.g., InGaN in a GaN matrix.

In some implementations, an etch-stop layer can be an AlGaN layer with an Al % content of greater than 10% and a thickness of at least 20 nm. In such implementations, an ICP etch can provide a selectivity better than 10:1 between AlGaN and GaN.

In some implementations, an etch-stop layer can form a residue after an etch operation. Accordingly, a residue removal step operation can be performed to remove the residue, which can be another etch operation, or other material removal operation.

In a general aspect, a microLED display includes a semiconductor member having a thickness, where the semiconductor member has a light emitting diode (LED) side configured to produce light for displaying an image, and an output side configured to display the image by outputting the produced light, the output side being opposite the LED side. The microLED display also includes a plurality of microLED mesas included on the LED side of the semiconductor member, and a plurality of etched features defined in the semiconductor member. The plurality of etched features are defined on at least one of the LED side or the output side. The plurality of etched features define un-etched portions in the semiconductor member having respective thicknesses that are less than the thickness of the semiconductor member. The respective thicknesses of the un-etched portions are uniform across the microLED display, with a total thickness variation less than 200 nanometers (nm).

Implementations can include one or more of the following features or aspects, alone or in combination. For example, the plurality of microLED mesas can be respectively included in a plurality of pixels of the microLED display. The plurality of pixels can respectively have at least one etched feature. Including the microLED mesas in a plurality of pixels can mean to arrange the plurality of LED mesas to form (or correspond to) pixels, or sub-pixels of a microLED display.

The plurality of etched features can have respective depths of greater than or equal to 500 nm.

The semiconductor member can include an etch-stop layer. Respective bottom surfaces of the plurality of etched features can be proximate the etch-stop layer.

An etched feature of the plurality of etched features can have vertical sidewalls.

An etched feature of the plurality of etched features can have sloped sidewalls with an angle between 20 degrees and 70 degrees from vertical.

In another general aspect, a microLED display includes a semiconductor member having a light emitting diode (LED) side configured to produce light for displaying an image, and an output side configured to display the image by outputting the produced light. The output side is opposite the LED side. The microLED display also includes a plurality of microLED mesas included on the LED side of the semiconductor member. The plurality of microLED mesas have respective base interfaces with the semiconductor member. The microLED display further includes a plurality of etched features defined in the semiconductor member on the output side. The plurality of etched features have respective bottom surfaces. Respective distances between the respective base interfaces and the respective bottom surfaces are uniform across the microLED display, with a total thickness variation less than 200 nanometers.

Implementations can include one or more of the following features or aspects, alone or in combination. For example, the plurality of microLED mesas can be respectively included in a plurality of pixels of the microLED display. The plurality of pixels can respectively have at least one etched feature.

The plurality of etched features can have respective depths of greater than or equal to 500 nm.

The semiconductor member can include an etch-stop layer. The respective bottom surfaces of the plurality of etched features can be proximate the etch-stop layer.

The plurality of microLED mesas can be respectively included in a plurality of pixels of the microLED display. The plurality of pixels can respectively have at least one etched feature.

An etched feature of the plurality of etched features can have vertical sidewalls.

An etched feature of the plurality of etched features can have sloped sidewalls with an angle between 20 degrees and 70 degrees from vertical.

In another general aspect, a method for forming a microLED display includes attaching a semiconductor stack to a backplane, where the semiconductor stack includes a substrate, a semiconductor template having a first etch-stop layer and a second etch-stop layer included therein, and LED layers. The attaching electrically couples the backplane to the LED layers. The method further includes removing the substrate, and etching the semiconductor template with a first etch process. The first etch process has a first etch rate for a first portion of the semiconductor template and a second etch rate for the first etch-stop layer. The second etch rate is slower than the first etch rate. Etching the semiconductor template produces lateral regions of the semiconductor template with a first uniform thickness. The method also includes etching the lateral regions of the semiconductor template with a second etch process having a third etch rate for a second portion of the semiconductor template and a fourth etch rate for the second etch-stop layer. The fourth etch rate is slower than the third etch rate. Etching the lateral regions of the semiconductor template defines un-etched portions of the lateral regions having a second uniform thickness that is less than the first uniform thickness.

Implementations can include one or more of the following features or aspects, alone or in combination. For example, the first uniform thickness can vary by less than +/−100 nanometers across the microLED display. The second uniform thickness can vary by less than +/−100 nanometers across the microLED display.

A ratio of the first etch rate to the second etch rate can be greater than or equal to 2.

A ratio of the third etch rate to the fourth etch rate can be greater than or equal to 2.

The semiconductor template can further include a third etch-stop layer, and the method can include, prior to attaching the semiconductor stack to the backplane, etching the LED layers with a third etch process to define a plurality of microLED mesas. The third etch process can have a fifth etch rate for the LED layers and a sixth etch rate for the third etch-stop layer. The sixth etch rate can be slower than the fifth etch rate. Etching the LED layers can define the plurality of microLED mesas having respective base interfaces that proximate the third etch-stop layer.

The first portion of the semiconductor template can include undoped semiconductor material.

The second portion of the semiconductor template can include doped semiconductor material.

In an example implementations, a microLED display can include a semiconductor member including a light emitting diode (LED) side configured to produce light for displaying an image; and an output side configured to display the image by outputting the produced light, the output side being opposite the LED side. The microLED display can include a plurality of microLED mesas included on the LED side of the semiconductor member, where the plurality of microLED mesas have respective base interfaces with the semiconductor member. The microLED display can include a plurality of etched features defined in the semiconductor member on the output side, where the plurality of etched features have respective bottom surfaces. Respective distances between the respective base interfaces and the respective bottom surfaces can be uniform across the microLED display, with a total thickness variation less than 200 nanometers.

It will be understood, for purposes of this disclosure, that when an element, such as a layer, a region, or a substrate, is referred to as being on, disposed on, disposed in, connected to, electrically connected to, coupled to, or electrically coupled to another element, it may be directly on, connected or coupled to the other element, or one or more intervening elements may be present. In contrast, when an element is referred to as being directly on, directly disposed on, directly disposed in, directly connected to or directly coupled to another element or layer, there are no intervening elements or layers present. Although the terms directly on, direct in, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to, vertically adjacent to, or horizontally adjacent to.

Some implementations may be implemented using various semiconductor processing and/or packaging techniques. Some implementations may be implemented using various types of semiconductor processing techniques, such as epitaxial growth processes, associated with semiconductor substrates and materials including, but not limited to, for example, silicon (Si), gallium arsenide (GaAs), gallium nitride (GaN), silicon carbide (SiC), and/or so forth.

While certain features of various example implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A microLED display comprising:
a semiconductor member having a thickness, the semiconductor member including:
a light emitting diode (LED) side configured to produce light for displaying an image; and
an output side configured to display the image by outputting the produced light, the output side being opposite the LED side;
a plurality of microLED mesas included on the LED side of the semiconductor member; and
a plurality of etched features defined in the semiconductor member, the plurality of etched features being defined on at least one of the LED side or the output side, the plurality of etched features defining un-etched portions in the semiconductor member having respective thicknesses that are less than the thickness of the semiconductor member,
the respective thicknesses of the un-etched portions being uniform across the microLED display, with a total thickness variation less than 200 nanometers (nm).

2. The microLED display of claim 1, wherein the plurality of microLED mesas are respectively included in a plurality of pixels of the microLED display, the plurality of pixels respectively having at least one etched feature.

3. The microLED display of claim 1, wherein the plurality of etched features have respective depths of greater than or equal to 500 nm.

4. The microLED display of claim 1, wherein:
the semiconductor member includes an etch-stop layer; and
respective bottom surfaces of the plurality of etched features are proximate the etch-stop layer.

5. The microLED display of claim 1, wherein a first etched feature of the plurality of etched features has vertical sidewalls.

6. The microLED display of claim 1, wherein a etched feature of the plurality of etched features has sloped sidewalls with an angle between 20 degrees and 70 degrees from vertical.

7. A microLED display comprising:
a semiconductor member including:
a light emitting diode (LED) side configured to produce light for displaying an image; and
an output side configured to display the image by outputting the produced light, the output side being opposite the LED side;
a plurality of microLED mesas included on the LED side of the semiconductor member, the plurality of microLED mesas having respective base interfaces with the semiconductor member; and
a plurality of etched features defined in the semiconductor member on the output side, the plurality of etched features having respective bottom surfaces,
respective distances between the respective base interfaces and the respective bottom surfaces being uniform across the microLED display, with a total thickness variation less than 200 nanometers.

8. The microLED display of claim 7, wherein the plurality of microLED mesas are respectively included in a plurality of pixels of the microLED display, the plurality of pixels respectively having at least one etched feature.

9. The microLED display of claim 7, wherein the plurality of etched features have respective depths of greater than or equal to 500 nm.

10. The microLED display of claim 7, wherein:
the semiconductor member includes an etch-stop layer; and
the respective bottom surfaces of the plurality of etched features are proximate the etch-stop layer.

11. The microLED display of claim 7, wherein the plurality of microLED mesas are respectively included in a plurality of pixels of the microLED display, the plurality of pixels respectively having at least one etched feature.

12. The microLED display of claim 7, wherein a first etched feature of the plurality of etched features has vertical sidewalls.

13. The microLED display of claim 7, wherein an etched feature of the plurality of etched features has sloped sidewalls with an angle between 20 degrees and 70 degrees from vertical.

14. A method for forming a microLED display, the method comprising:
attaching a semiconductor stack to a backplane, the semiconductor stack including a substrate, a semiconductor template having a first etch-stop layer and a second etch-stop layer included therein, and LED layers, the attaching electrically coupling the backplane to the LED layers;
removing the substrate;
etching the semiconductor template with a first etch process having first etch rate for a first portion of the semiconductor template and a second etch rate for the first etch-stop layer, the second etch rate being slower than the first etch rate, the etching the semiconductor template producing lateral regions of the semiconductor template with a first uniform thickness; and
etching the lateral regions of the semiconductor template with a second etch process having a third etch rate for a second portion of the semiconductor template and a fourth etch rate for the second etch-stop layer, the fourth etch rate being slower than the third etch rate, the etching the lateral regions of the semiconductor template defining un-etched portions of the lateral regions having a second uniform thickness that is less than the first uniform thickness.

15. The method of claim 14, wherein:
the first uniform thickness varies by less than +/−100 nanometers across the microLED display; and
the second uniform thickness varies by less than +/−100 nanometers across the microLED display.

16. The method of claim 14, wherein a ratio of the first etch rate to the second etch rate is greater than or equal to 2.

17. The method of claim 14, wherein a ratio of the third etch rate to the fourth etch rate is greater than or equal to 2.

18. The method of claim 14, wherein the semiconductor template further includes a third etch-stop layer, the method further comprising:
prior to attaching the semiconductor stack to the backplane, etching the LED layers with a third etch process to define a plurality of microLED mesas, the third etch process having a fifth etch rate for the LED layers and a sixth etch rate for the third etch-stop layer, the sixth etch rate being slower than the fifth etch rate, the etching the LED layers defining the plurality of microLED mesas having respective base interfaces that are proximate the third etch-stop layer.

19. The method of claim 14, wherein the first portion of the semiconductor template includes undoped semiconductor material.

20. The method of claim 14, wherein the second portion of the semiconductor template includes doped semiconductor material.
